(19) United States
(12) Patent Application Publication
(10) Pub. No.: US 2016/0003888 A1
(43) Pub. Date: Jan. 7, 2016

(54) Method of characterizing a device

(71) Applicant: United Microelectronics Corp., Hsin-Chu City (TW)

(72) Inventors: Wen-Yin Weng, Taichung City (TW); Wei-Heng Hsu, Kaohsiung City (TW); Cheng-Tung Huang, Kaohsiung City (TW); Yi-Ting Wu, Taipei City (TW); Yu-Ming Lin, Tainan City (TW); Jen-Yu Wang, Tainan City (TW)

(21) Appl. No.: 14/321,841

(22) Filed: Jul. 2, 2014

(51) Int. Cl. G01R 31/26

(52) U.S. Cl. CPC G01R 31/2607

(57) ABSTRACT

A method of characterizing a device may be used to determine a metal work function of the device according to a threshold voltage, a body effect, and an oxide capacitance of the device. The threshold voltage may be determined according to a current to voltage curve. The oxide capacitance may be determined according to a capacitor to voltage curve.

### BACKGROUND OF THE INVENTION

1. Field of the Invention

The present invention discloses a method of characterizing a device, and more particularly a method of characterizing a high-k metal gate technology device.

2. Description of the Prior Art

During a high-k metal gate fabrication process, the metal work function needs to be tuned. Therefore, accurate extraction and monitoring of the metal work function are important. A capacitor to voltage measurement may be performed to determine the metal work function. In such method, the metal work function of at least a core device and an input/output device may be determined. This is to account for the difference in the oxide thickness of the core device and the input/output device. Therefore, there is a need for a method of characterizing a device that need not use multiple devices in order to determine the characteristics of the device.

### SUMMARY OF THE INVENTION

An embodiment of a method of characterizing a device is disclosed. The method of characterizing a device comprises generating a current to voltage curve of the device, determining a threshold voltage of the device according to the current to voltage curve, determining a body effect of the device, generating a capacitor to voltage curve of the device, determining an oxide capacitance of the device according to the capacitor to voltage curve, and determining a metal work function of the device according to the threshold voltage, the body effect, and the oxide capacitance.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a flowchart of a method of characterizing a device according to an embodiment of the present invention.

FIG. 2 illustrates a current to voltage curve of a device according to an embodiment of the present invention.

FIG. 3 illustrates a capacitor to voltage curve of a device according to an embodiment of the present invention.

### DETAILED DESCRIPTION

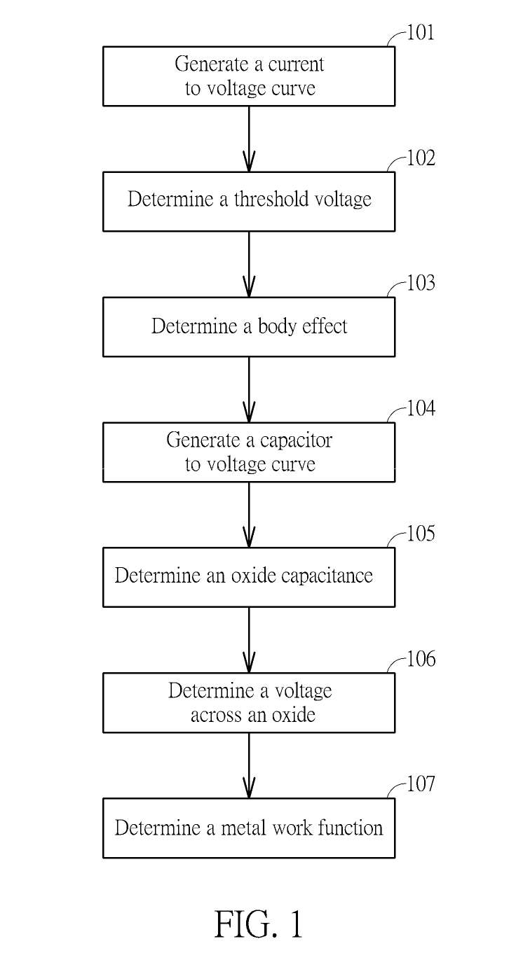

FIG. 1 illustrates a flowchart of a method of characterizing a device according to an embodiment of the present invention. The method of characterizing the device may include but is not limited to the following steps:

Step 101: Generate a current to voltage curve of the device;

Step 102: Determine a threshold voltage of the device according to the current to voltage curve;

Step 103: Determine a body effect of the device

Step 104: Generate a capacitor to voltage curve of the device;

Step 105: Determine an oxide capacitance of the device according to the capacitor to voltage curve;

Step 106: Determine a voltage across an oxide of the device corresponding to the fixed charge; and

Step 107: Determine a metal work function of the device according to the threshold voltage, the body effect, and the oxide capacitance.

The device being characterized may be a high-k metal gate metal oxide semiconductor field effect transistor (MOSFET). The device may be a core device of a die of a wafer fabricated using high-k metal gate fabrication technology. A semiconductor analyzer may be used for generating the current to voltage curve of the device and generating the capacitor to voltage curve of the device.

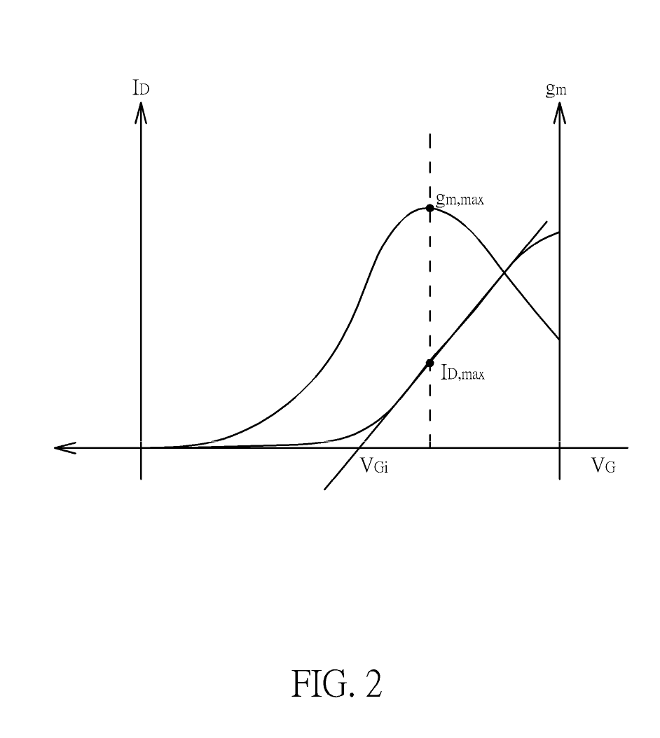

In step 101, the current to voltage curve of the device may be generated. The current to voltage curve of the device may include generating a drain current I_{D} of the device according to a changing value of a gate voltage V_{G} of the device. Hereafter, the curve showing the drain current I_{D} against the gate voltage V_{G} may be referred to as a drain current curve. FIG. 2 illustrates a current to voltage curve of a device according to an embodiment of the present invention. The current to voltage curve of the device may also include generating a transconductance gₘ of the device against the gate voltage V_{G} of the device. Hereafter, the curve showing the transconductance gₘ against the gate voltage V_{G} may be referred to as a transconductance curve.

In step 102, the threshold voltage V_{T} of the device may be determined according to the current to voltage curve. The threshold voltage may be determined according to the maximum transconductance g_{m,max} of the device. From the transconductance curve, the maximum transconductance g_{m,max} of the device may be determined. A straight line may be fitted to the drain current curve according to the maximum transconductance g_{m,max} to determine the maximum drain current I_{D,max}. A tangent line of the drain current curve at the maximum drain current I_{D,max} point is made and a corresponding gate voltage V_{Gi} is extrapolated from the tangent line. The corresponding gate voltage V_{Gi} is a gate voltage V_{G} of the tangent line when a level of the drain current I_{D} is equal to 0. The threshold voltage V_{T} may be determined using the following equation:

V_{T}=V_{Gi}−V_{DS}/2

where V_{DS} is the drain to source voltage of the device.

In step 103, the determining of the body effect of the device may include the determining of a body potential φ_{B}, a doping density Na, and a substrate work function φₛ of the device. Determining the body potential φ_{B} and the doping density Na of the device comprises determining the body potential and the doping density using a threshold voltage equation as a function of a substrate bias. The threshold voltage equation as a function of a substrate bias is as follows:

ΔV_{T}=[(2εₛqNa)^{1/2}]/C_{OX}[(2φ_{B}+V_{SB})^{1/2}−(2φ_{B})^{1/2}]

wherein ΔV_{T} is the threshold voltage of the device, φ_{B} is the body potential of the device, V_{SB} is the substrate bias of the device, C_{OX} is the oxide capacitance of the device, Na is the doping density of the device, q is a charge of an electron, and εₛ is a permittivity of a silicon.

A substrate bias V_{SB} and an initial body potential may be set. An initial doping density according to the substrate bias V_{SB} and the initial body potential may be determined. The body potential φ_{B} of the device may be determined. The doping density Na of the device maybe determined. Determining the body potential φ_{B} and determining the doping density Na are repeated until the body potential φ_{B} and the doping density Na determined are constant with a previously determined body potential φ_{B} and a previously determined doping density Na. There may be at least two iterations to determine the constant body potential φ_{B} and doping density Na.

The body potential φ_{B} may be determined using the following equation:

φ_{B}=kT/q ln(Na/nᵢ)

where k is Boltzmann constant, T is the temperature, q is the charge of an electron, and nᵢ is the intrinsic carrier density.

A substrate work function φₛ of the device may be determined according to the body potential φ_{B} and the doping density Na. The substrate work function φₛ may be determined using the following equation:

qφₛ=qx+Eg/2+qφ_{B}

where φ₃ is a body potential of the device, q is a charge of an electron, φₛ is the substrate work function of the device, x is an electron affinity, and Eg is a bandgap.

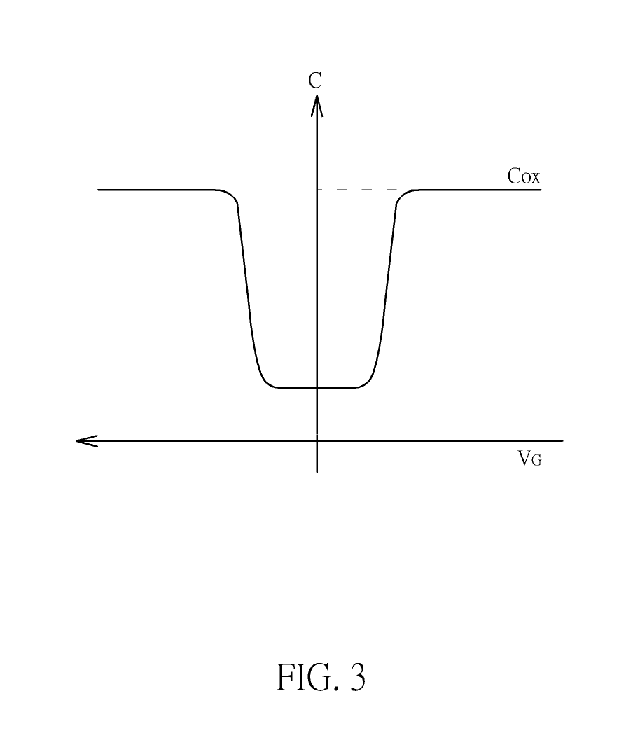

In step 104, the capacitor to voltage curve of the device may be generated. The capacitor to voltage curve may include generating a capacitance per unit area of the device according to a changing value of a gate voltage V_{G} of the device. FIG. 3 illustrates a capacitor to voltage curve of a device according to an embodiment of the present invention.

In step 105, an oxide capacitance of the device according to the capacitor to voltage curve may be determined. Wherein, the maximum capacitance of the capacitor to voltage curve may be the oxide capacitance C_{OX} of the device.

In step 106, a voltage across an oxide Q_{f}/C_{OX} of the device corresponding to the fixed charge may be determined. A fixed charge Q_{f} of the device may be set accordingly. For a typical case, the fixed charge Q_{f} of the device may be set at 1e¹⁰ [1/cm²]. If so, the voltage across an oxide Q_{f}/C_{OX} of the device may be around 1 mV. The value of the voltage across an oxide Q_{f}/C_{OX} may be low enough to be ignored in some embodiments of the present invention.

In step 107, the metal work function φₘ of the device may be determined according the threshold voltage V_{T}, the body effect, and the oxide capacitance C_{OX} of the device. The metal work function φₘ of the device may be determined using the following equation:

Vₜ=φₘ−φₛ+2φ_{B}+[(4εₛqNaφ_{B})^{1/2}]/C_{OX}

wherein Vₜ is the threshold voltage of the device, φ_{B} is a body potential of the device, C_{Ox} is the oxide capacitance of the device, Na is the doping density of the device, q is a charge of an electron, εₛ is a permittivity of a silicon, φₘ is the metal work function of the device, and φₛ is the substrate work function of the device.

Furthermore, for a more precise metal work function φₘ the voltage across an oxide Q_{f}/C_{OX} of the device may be used to determine the metal work function φₘ. The metal work function φₘ of the device may be determined using the following equation:

Vₜ=φₘ−φₛ−Q_{f}C_{OX}+2φ_{B}+[(4εₛqNaφ_{B})^{1/2}]/C_{OX}

wherein Vₜ is the threshold voltage of the device, φ_{B} is a body potential of the device, C_{OX} is the oxide capacitance of the device, Na is the doping density of the device, q is a charge of an electron, εₛ is a permittivity of a silicon, φₘ is the metal work function of the device, φₛ is the substrate work function of the device, and Q_{f} is the fixed charge of the device.

The present invention presents a method of characterizing a device wherein the device may be fabricated using a high-k metal gate technology process. The method may use a single device to determine a metal work function of the device. The single device may be a core device or an input/output device. The extracted metal work function determined may be the metal work function of a die. The use of the method may enable extracting of the metal work function of each of the die of a wafer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of characterizing a device, comprising:
generating a current to voltage curve of the device;
determining a threshold voltage of the device according to the current to voltage curve;
determining a body effect of the device;
generating a capacitor to voltage curve of the device;
determining an oxide capacitance of the device according to the capacitor to voltage curve; and
determining a metal work function of the device according to the threshold voltage, the body effect, and the oxide capacitance.

2. The method of claim 1, wherein determining the metal work function of the device further comprises determining the metal work function of the device using a threshold voltage equation as follows:
Vₜ=φₘ−φₛ+2φ_{B}+[(4εₛqNaφ_{B})^{1/2}]/C_{OX}
wherein Vₜ is the threshold voltage of the device, φ_{B} is a body potential of the device, C_{OX} is the oxide capacitance of the device, Na is a doping density of the device, q is a charge of an electron, εₛ is a permittivity of a silicon, φₘ is the metal work function of the device, and φₛ is a substrate work function of the device.

3. The method of claim 1, further comprising:
setting a fixed charge of the device; and
determining a voltage across an oxide of the device corresponding to the fixed charge.

4. The method of claim 3, wherein determining the metal work function of the device further comprises determining the metal work function of the device using a threshold voltage equation as follows:
Vₜ=φₘ−φₛ−Q_{f}/C_{OX}+2φ_{B}+[(4εₛqNaφ_{B})^{1/2}]/C_{OX}
wherein Vₜ is the threshold voltage of the device, φ_{B} is a body potential of the device, C_{OX} is the oxide capacitance of the device, Na is a doping density of the device, q is a charge of an electron, εₛ is a permittivity of a silicon, φₘ is the metal work function of the device, φₛ is a substrate work function of the device, and Q_{f} is the fixed charge of the device.

5. The method of claim 1, further comprising generating a drain current to gate voltage curve of the device when generating the current to voltage curve of the device.

6. The method of claim 1, wherein determining the body effect of the device comprises :
setting a substrate bias and an initial body potential;
determining an initial doping density according to the substrate bias and the initial body potential;
determining a body potential of the device;
determining a doping density of the device; and
determining a substrate work function of the device according to the body potential and the doping density;
wherein determining the body potential and determining the doping density are repeated until the body potential and the doping density determined are constant with a previously determined body potential and a previously determined doping density.

7. The method of claim 6, wherein determining the body potential and the doping density of the device comprises determining the body potential and the doping density using a threshold voltage equation as a function of a substrate bias as follows:
ΔV_{T}=[(2εₛqNa)^{1/2}]/C_{OX}[(2φ_{B}+V_{SB})^{1/2}−(2φ_{B})^{1/2}]
wherein ΔV_{T} is the threshold voltage of the device, φ_{B} is the body potential of the device, V_{SB} is the substrate bias of the device, C_{OX} is the oxide capacitance of the device, Na is the doping density of the device, q is a charge of an electron, and εₛ is a permittivity of a silicon.

8. The method of claim 7, wherein determining the substrate work function further comprises determining the substrate work function using a substrate work function equation as follows:
qφₛ=qx+Eg/2+qφ_{B}
wherein φ₃ is the body potential of the device, q is the charge of the electron, φₛ is the substrate work function of the device, x is an electron affinity, and Eg is a bandgap.

9. The method of claim 1, further comprising using a semiconductor analyzer for generating the current to voltage curve of the device and for generating the capacitor to voltage curve of the device.
